(19) United States
(12) Patent Application Publication
(10) Pub. No.: US 2025/0107129 A1
(43) Pub. Date: Mar. 27, 2025

(54) METHOD FOR MANUFACTURING SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Masaharu SHIMABAYASHI, Ibo Hyogo (JP)

(21) Appl. No.: 18/649,568

(22) Filed: Apr. 29, 2024

(30) Foreign Application Priority Data
Sep. 25, 2023 (JP) 2023-159951

(51) Int. Cl. H01L 29/66; H01L 21/28

(52) U.S. Cl. CPC H10D 30/0291; H01L 21/28194

(57) ABSTRACT

In a method for manufacturing a semiconductor device according to one embodiment, an opening is formed in an upper surface of a first semiconductor region of a first conductivity type. In the method, a gap is formed at a lower portion of the opening by performing atomic layer deposition to plug the opening by forming a first insulating layer at an upper portion of the opening. In the atomic layer deposition, adsorption of an inhibitor to an inner surface of the lower portion of the opening, or termination of dangling bonds of a semiconductor material present at the inner surface of the lower portion of the opening, and adsorption of a precursor to an inner surface of the upper portion of the opening are repeatedly performed.

### CROSS-REFERENCE TO RELATED APPLICATIONS

This application is based upon and claims the benefit of priority from Japanese Patent Application No. 2023-159951, filed on Sep. 25, 2023; the entire contents of which are incorporated herein by reference.

### FIELD

Embodiments of the invention generally relate to a method for manufacturing a semiconductor device.

### BACKGROUND

There is a semiconductor device in which a gap is provided. There is a need for technology that can suppress dimensional and shape fluctuation of the gap in such a semiconductor device.

### BRIEF DESCRIPTION OF THE DRAWINGS

FIG. 1 is a plan view showing a semiconductor device manufactured by a manufacturing method according to an embodiment;

FIG. 2 is a plan view showing the semiconductor device manufactured by the manufacturing method according to the embodiment;

FIG. 3 is a plan view showing the semiconductor device manufactured by the manufacturing method according to the embodiment;

FIG. 4A is an A-A′ cross-sectional view of FIGS. 2 and 3, and FIG. 4B is a B-B′ cross-sectional view of FIGS. 2 and 3;

FIG. 5 is a C-C′ cross-sectional view of FIGS. 2 and 3;

FIGS. 6A to 6D are process cross-sectional views showing a method for manufacturing the semiconductor device according to the embodiment;

FIGS. 7A to 7D are process cross-sectional views showing the method for manufacturing the semiconductor device according to the embodiment;

FIGS. 8A to 8D are process cross-sectional views showing the method for manufacturing the semiconductor device according to the embodiment;

FIGS. 9A to 9D are process cross-sectional views showing the method for manufacturing the semiconductor device according to the embodiment;

FIGS. 10A and 10B are process cross-sectional views showing the method for manufacturing the semiconductor device according to the embodiment; and

FIGS. 11A to 11G are process cross-sectional views showing a manufacturing method according to a modification of the embodiment.

### DETAILED DESCRIPTION

In a method for manufacturing a semiconductor device according to one embodiment, an opening is formed in an upper surface of a first semiconductor region of a first conductivity type. In the method, a gap is formed at a lower portion of the opening by performing atomic layer deposition to plug the opening by forming a first insulating layer at an upper portion of the opening. In the atomic layer deposition, adsorption of an inhibitor to an inner surface of the lower portion of the opening, or termination of dangling bonds of a semiconductor material present at the inner surface of the lower portion of the opening, and adsorption of a precursor to an inner surface of the upper portion of the opening are repeatedly performed.

Various embodiments will be described hereinafter with reference to the accompanying drawings. The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions. In the specification and drawings, components similar to those described or illustrated in a drawing therein above are marked with like reference numerals, and a detailed description is omitted as appropriate.

In the following description, the notations of n⁺, n⁻, p⁺, and p indicate relative levels of the impurity concentrations of the conductivity types. Namely, n⁺ indicates that the n-type impurity concentration is relatively higher than that of n. Also, p⁺ indicates that the p-type impurity concentration is relatively lower than that of p. When both a p-type impurity and an n-type impurity are included in each region, these notations indicate relative levels of the net impurity concentrations after the impurities compensate each other.

According to the embodiments described below, each embodiment may be implemented by inverting the p-type and the n-type of the semiconductor regions.

### Semiconductor Device

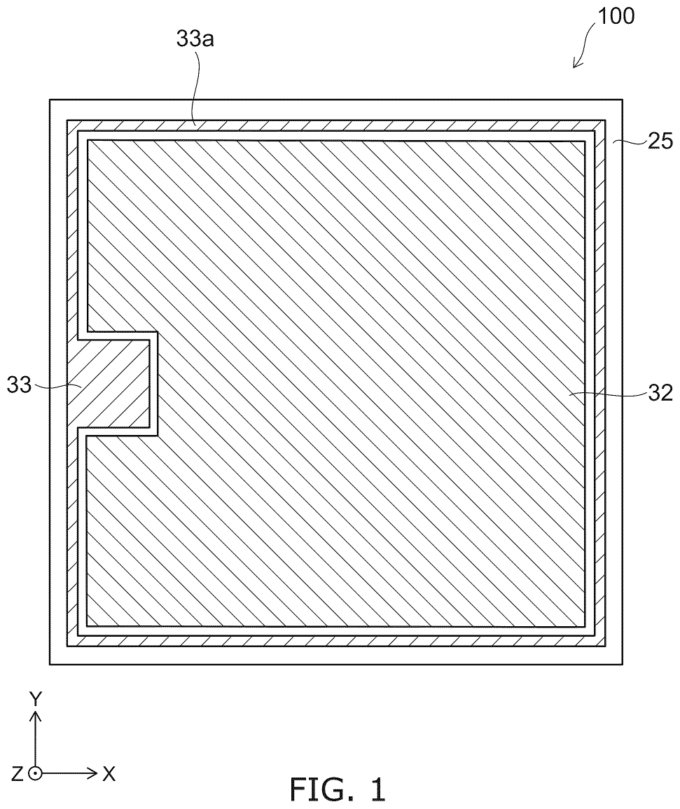

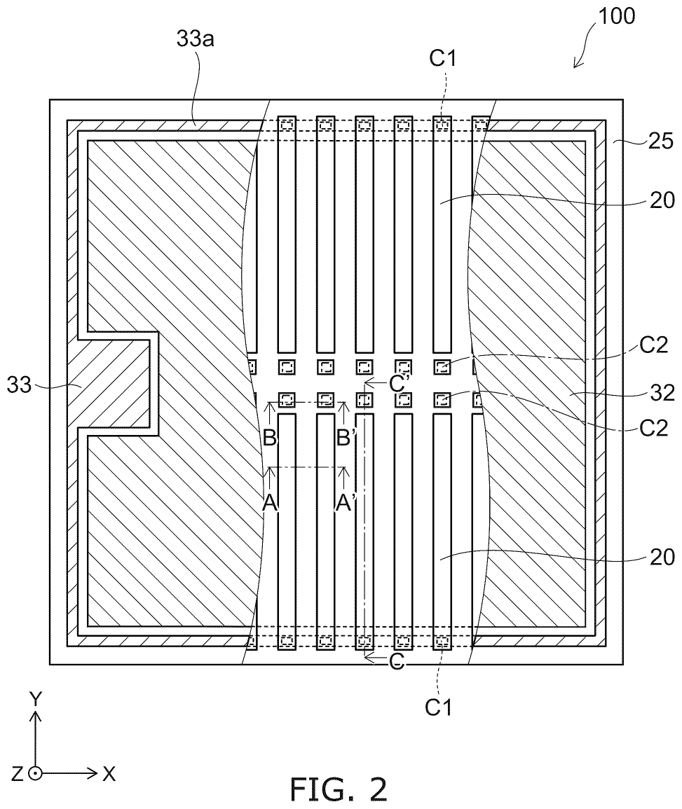

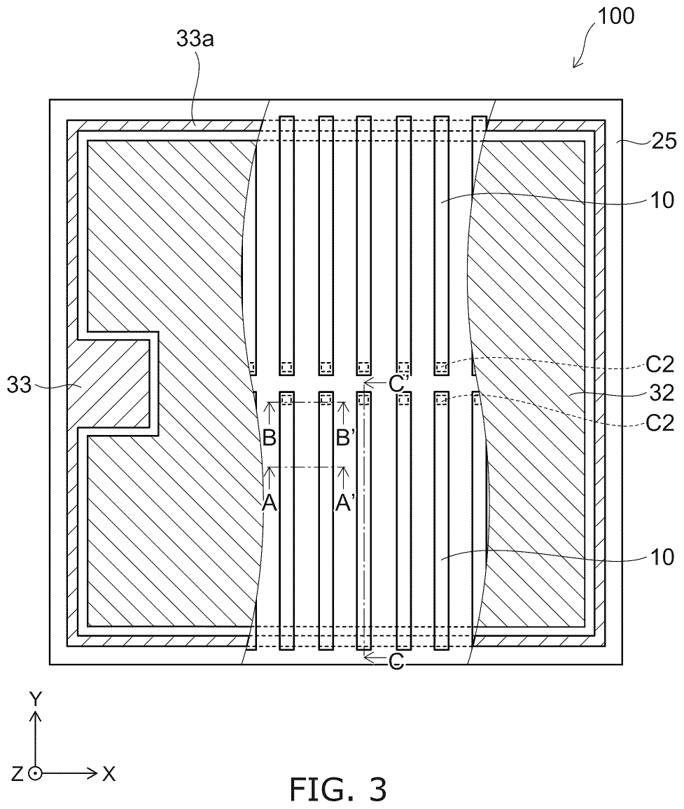

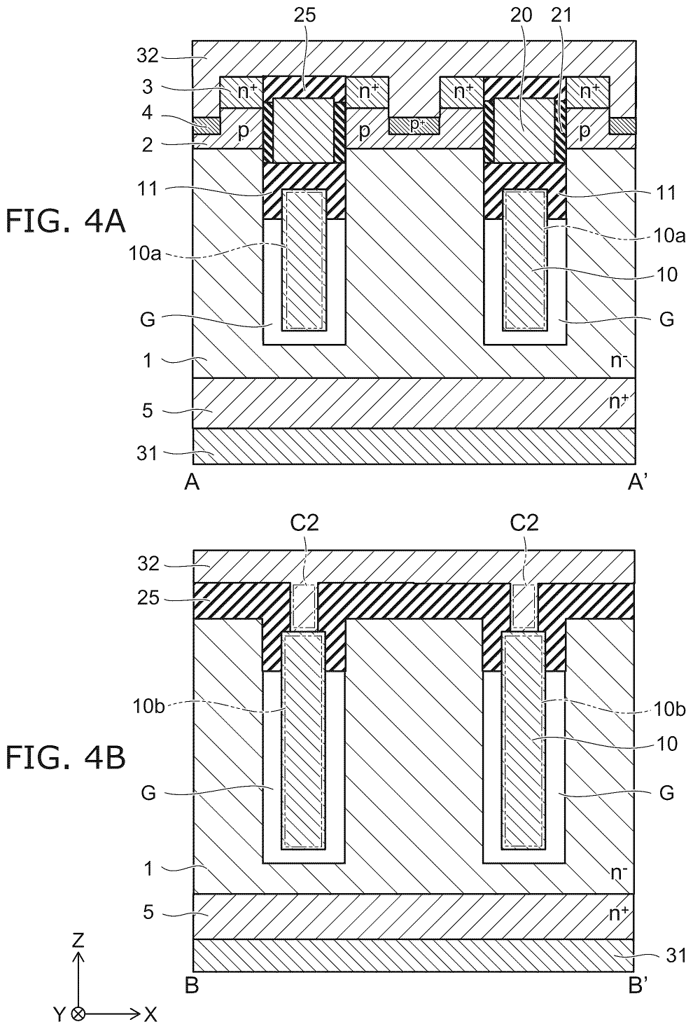

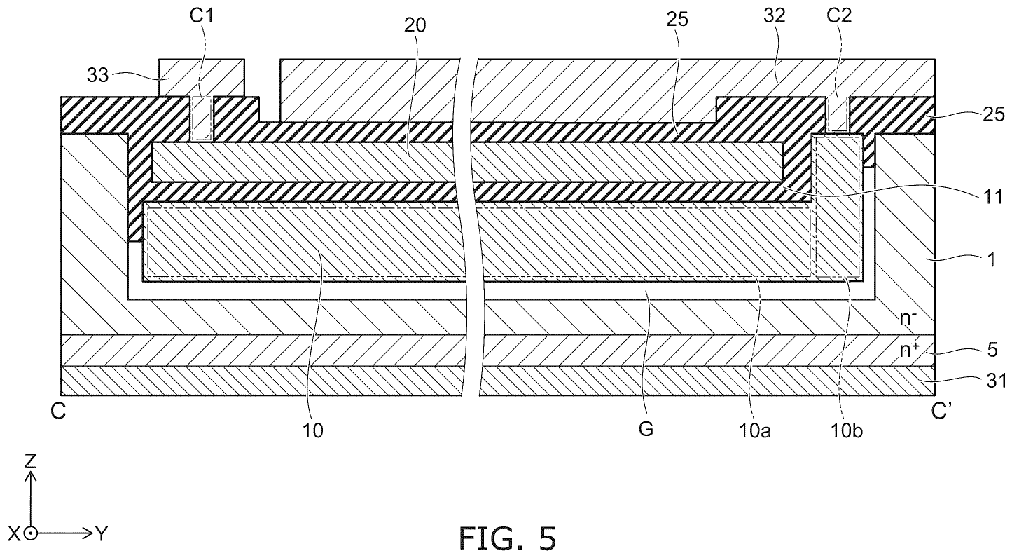

FIGS. 1 to 3 are plan views showing a semiconductor device manufactured by a manufacturing method according to an embodiment. FIG. 4A is an A-A′ cross-sectional view of FIGS. 2 and 3. FIG. 4B is a B-B′ cross-sectional view of FIGS. 2 and 3. FIG. 5 is a C-C′ cross-sectional view of FIGS. 2 and 3. The semiconductor device 100 shown in FIGS. 1 to 5 is a MOSFET. The semiconductor device 100 includes an n-type (first-conductivity-type) drift region 1 (a first semiconductor region), a p-type (second-conductivity-type) base region 2 (a second semiconductor region), an n⁺-type source region 3 (a third semiconductor region), a p⁺-type contact region 4, an n⁺-type drain region 5, a FP electrode 10 (a conductive part), an insulating layer 11, a gate electrode 20, a gate insulating layer 21, an insulating layer 25, a drain electrode 31 (a first electrode), a source electrode 32 (a second electrode), a gate pad 33, and a wiring part 33a. To illustrate the gate electrode 20 in FIG. 2, portions of the insulating layer 25, the source electrode 32, and the wiring part 33a are see-through. To illustrate the field plate electrode (hereinbelow, called the FP electrode) 10 in FIG. 3, portions of the gate electrode 20, the insulating layer 25, the source electrode 32, and the wiring part 33a are see-through.

An XYZ orthogonal coordinate system is used in the description of embodiments. The direction from the drain electrode 31 toward the n-type drift region 1 is taken as a Z-direction (a first direction). Two mutually-orthogonal directions perpendicular to the Z-direction are taken as an X-direction (a third direction) and a Y-direction (a second direction). In the description, the direction from the drain electrode 31 toward the n-type drift region 1 is called “up/above/higher than”, and the opposite direction is called “down/below/lower than”. These directions are based on the relative positional relationship between the drain electrode 31 and the n⁻-type drift region 1, and are independent of the direction of gravity.

As shown in FIG. 1, the source electrode 32 and the gate pad 33 are located at the upper surface of the semiconductor device 100. The source electrode 32 and the gate pad 33 are separated from each other, and are electrically isolated from each other. The wiring part 33a is electrically connected to the gate pad 33. The wiring part 33a is located around the source electrode 32. The portion of the upper surface of the semiconductor device 100 other than the source electrode 32, the gate pad 33, and the wiring part 33a is covered with the insulating layer 25.

As shown in FIG. 2, multiple gate electrodes 20 are arranged in the X-direction and Y-direction; and each gate electrode 20 extends in the Y-direction. A Y-direction end portion of each gate electrode 20 is electrically connected with the wiring part 33a via a connection part C1.

A portion of the FP electrode 10 is located under the gate electrode 20. As shown in FIG. 3, multiple FP electrodes 10 are arranged in the X-direction and Y-direction; and each FP electrode 10 extends in the Y-direction. A Y-direction end portion of each FP electrode 10 is electrically connected with the source electrode 32 via a connection part C2.

As shown in FIGS. 4A, 4B, and 5, the drain electrode 31 is located at the lower surface of the semiconductor device 100. The n⁺-type drain region 5 is located on the drain electrode 31, and is electrically connected with the drain electrode 31. The n⁻-type drift region 1 is located on the n⁺-type drain region 5. The n-type impurity concentration of the n-type drift region 1 is less than the n-type impurity concentration of the n⁺-type drain region 5.

The FP electrode 10 is located inside the n-type drift region 1 with a gap G interposed. The FP electrode 10 includes a first conductive part 10a and a second conductive part 10b. The first conductive part 10a is positioned under the gate electrode 20, and extends in the Y-direction. The second conductive part 10b is positioned at a Y-direction end portion of the FP electrode 10, and is connected with the connection part C2 of the source electrode 32. The Z-direction length of the second conductive part 10b is greater than the Z-direction length of the first conductive part 10a.

The insulating layer 11 is located around the upper portion of the first conductive part 10a, and is positioned on the gap G. The gate electrode 20 is located on the first conductive part 10a with the insulating layer 11 interposed.

As shown in FIG. 4A, the p-type base region 2 is located on the n-type drift region 1. The p-type base region 2 faces the gate electrode 20 via the gate insulating layer 21 in the X-direction. The n⁺-type source region 3 and the p⁺-type contact region 4 are located on the p-type base region 2.

The source electrode 32 is positioned on the n⁺-type source region 3 and the p⁺-type contact region 4, and is electrically connected with these semiconductor regions. In the illustrated example, a portion of the source electrode 32 is arranged with the n⁺-type source region 3 in the X-direction. The p⁺-type contact region 4 is located under the portion of the source electrode 32. The insulating layer 25 is located between the gate electrode 20 and the source electrode 32; and the gate electrode 20 and the source electrode 32 are electrically isolated from each other.

Operations of the semiconductor device 100 will now be described.

When a voltage that is not less than a threshold is applied to the gate electrode 20, a channel (an inversion layer) is formed at the gate insulating layer 21 vicinity of the p-type base region 2. When a channel is formed in a state in which a positive voltage with respect to the source electrode 32 is applied to the drain electrode 31, electrons flow from the source electrode 32 toward the n⁻-type drift region 1 via the channel. As a result, the semiconductor device 100 is set to an on-state.

Subsequently, when the voltage applied to the gate electrode 20 drops below the threshold, the semiconductor device 100 is switched to an off-state. When the semiconductor device 100 switches from the on-state to the off-state, a depletion layer spreads from the p-n junction surface of the n-type drift region 1 and the p-type base region 2 toward the n-type drift region 1. Simultaneously, a depletion layer spreads from the interface between the gap G and the n-type drift region 1 toward the n⁻-type drift region 1 due to the potential difference between the FP electrode 10 and the drain electrode 31. The breakdown voltage of the semiconductor device can be increased by the FP electrode 10 promoting depletion of the n-type drift region 1. Or, the n-type impurity concentration of the n-type drift region 1 can be increased by the amount of the breakdown voltage increase of the semiconductor device; and the on-resistance of the semiconductor device can be reduced.

Examples of the materials of the components will now be described.

The n-type drift region 1, the p-type base region 2, the n⁺-type source region 3, the p⁺-type contact region 4, and the n⁺-type drain region 5 include silicon, silicon carbide, gallium nitride, or gallium arsenide as a semiconductor material. When silicon is used as the semiconductor material, arsenic, phosphorus, or antimony can be used as an n-type impurity. Boron can be used as a p-type impurity. The FP electrode 10 and the gate electrode 20 include conductive materials such as polysilicon, etc. The insulating layer 11, the gate insulating layer 21, and the insulating layer 25 include insulating materials such as silicon oxide, silicon nitride, etc. The drain electrode 31, the source electrode 32, the gate pad 33, and the wiring part 33a include metal materials such as titanium, aluminum, etc.

### Manufacturing Method

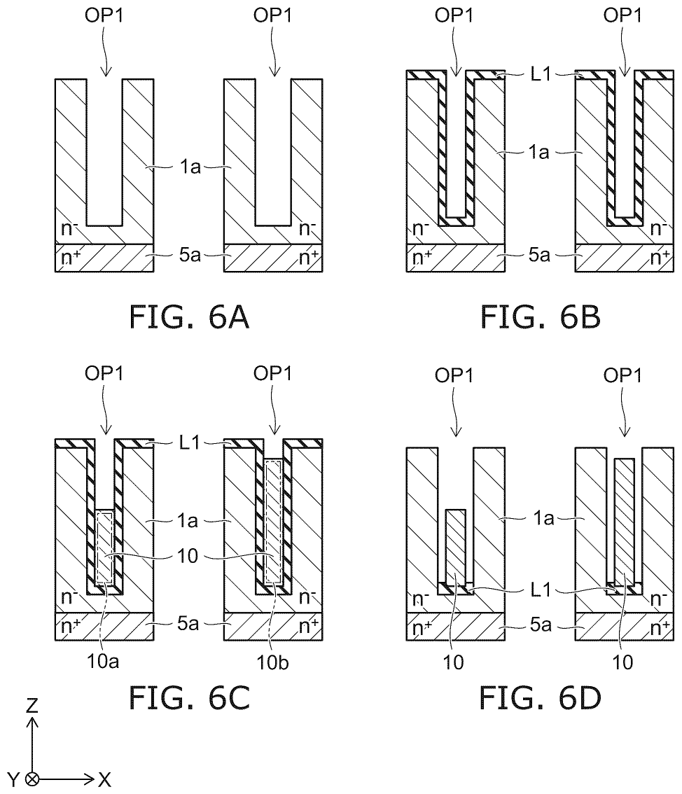

FIGS. 6A to 10B are process cross-sectional views showing a method for manufacturing the semiconductor device according to the embodiment. In the drawings of FIGS. 6A to 10B, the left side shows manufacturing processes at a portion of FIG. 3 at a position marked with line A-A′; and the right side shows manufacturing processes at a portion of FIG. 3 at a position marked with line B-B′.

First, a semiconductor substrate that includes an n⁺-type semiconductor layer 5a and an n-type semiconductor layer 1a is prepared. The n-type semiconductor layer 1a is located on the n⁺-type semiconductor layer 5a. As shown in FIG. 6A, multiple openings OP1 that extend in the Y-direction are formed in the upper surface of the n-type semiconductor layer 1a. As shown in FIG. 6B, a first layer L1 is formed along the inner surface of the opening OP1. The material of the first layer L1 is arbitrary as long as the material of the first layer L1 is different from the material of an insulating layer IL1 described below. For example, the first layer L1 is silicon nitride formed by chemical vapor deposition (CVD). Or, the first layer L1 may be a silicon oxide layer formed by thermal oxidation of the n-type semiconductor layer 1a.

A conductive layer is formed on the first layer L1. As shown in FIG. 6C, the FP electrode 10 that includes the first and second conductive parts 10a and 10b is formed by etching the conductive layer. As shown in FIG. 6D, a portion of the first layer L1 is removed by wet etching so that the upper end of the first layer L1 around the first conductive part 10a is positioned lower than the upper end of the first conductive part 10a. In the illustrated example, the portion of the first layer L1 other than the first layer L1 at the bottom portion of the opening OP1 is removed.

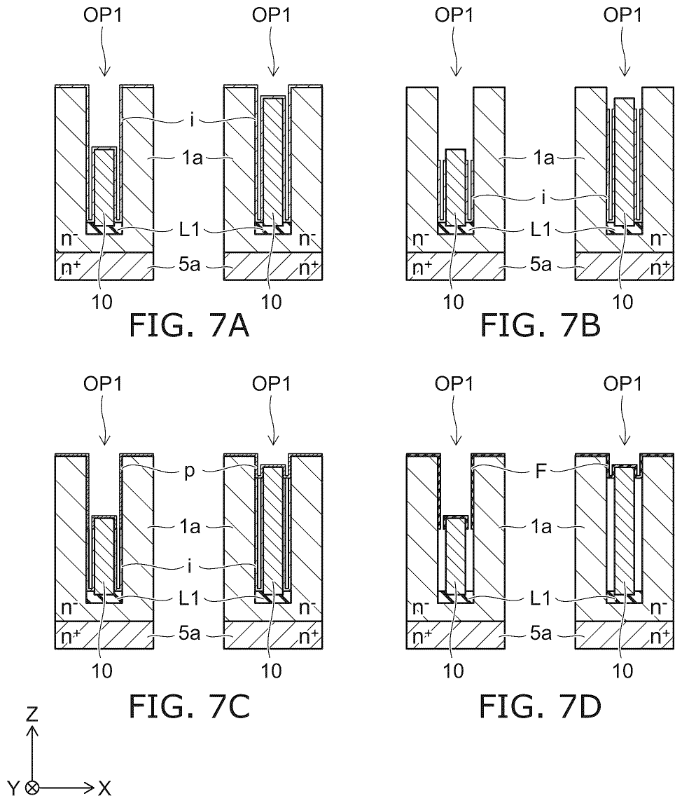

Subsequently, an insulating layer is formed on the FP electrode 10 by atomic layer deposition (ALD). Specifically, ALD includes the processes shown in FIGS. 7A to 7D. First, as shown in FIG. 7A, a particle called an inhibitor is adhered to the inner surface of the opening OP1 and the surface of the FP electrode 10. The inhibitor i suppresses the adhesion of a precursor described below to the inner surface of the opening OP1. A self-assembled monolayer (SAM) or a small molecule inhibitor (SMI) can be used as the inhibitor i.

The semiconductor substrate to which the inhibitor i is adhered is exposed to plasma of an inert gas. A portion of the adhered inhibitor i is removed by the plasma. At this time, the plasma does not easily reach the lower portion of the opening OP1. As a result, as shown in FIG. 7B, the inhibitor i that is adhered to the inner surface of the upper portion of the opening OP1 and the upper surface of the FP electrode 10 is removed.

Then, a precursor p is supplied to the semiconductor substrate. The precursor p does not adhere to the surface at which the inhibitor i is adhered. Therefore, as shown in FIG. 7C, the precursor p is selectively adhered to the inner surface of the upper portion of the opening OP1 and the upper surface of the FP electrode 10. When silicon oxide is formed by ALD, a Si ingredient such as tris(dimethylamino)silane (TDMAS), Orthrus® made by Air Liquide, bis(diethylamino)silane (SAM24), or the like can be used as the precursor. Subsequently, a gas that reacts with the precursor is supplied to the semiconductor substrate. An oxygen-including gas is used when forming silicon oxide. A nitrogen-including gas is used when forming silicon nitride. The gas reacts with the precursor, and an insulating thin film F is formed.

As shown in FIG. 7D, the inhibitor i that is adhered to the inner surface of the opening OP1 and the surface of the FP electrode 10 is removed. For example, the inhibitor i is removed by depressurizing a processing chamber in which the semiconductor substrate is placed. Subsequently, the process shown in FIG. 7A is re-performed. In the process shown in FIG. 7B, the inhibitor i that is adhered to the thin film F is removed.

In the case where the adhered inhibitor i can still function after the thin film F is formed, the processes shown in FIG. 7A and the drawing 7B may be omitted, and the process shown in FIG. 7C may be performed. In such a case, the processes shown in FIGS. 7A and 7B are performed as appropriate when the function of the inhibitor i has degraded.

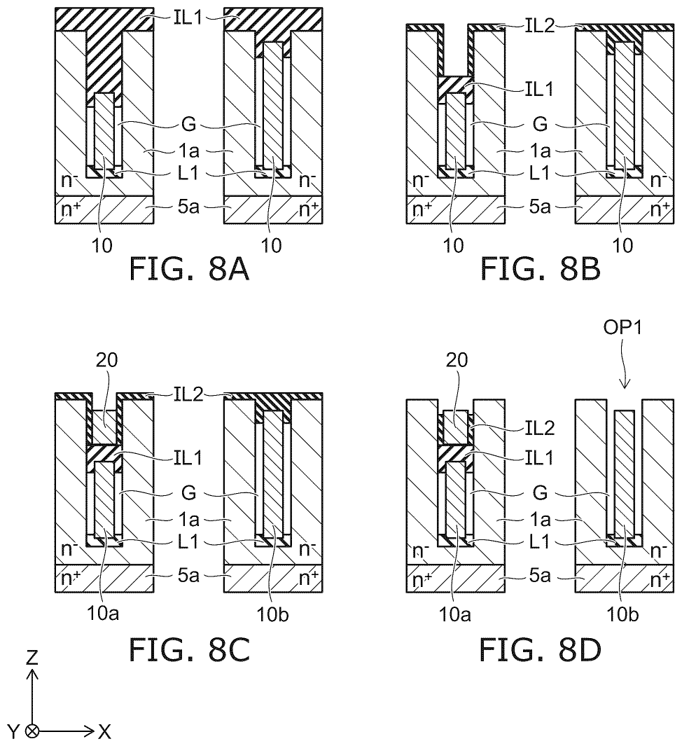

The thin film F gradually is made thicker by repeating the processes shown in FIGS. 7A to 7D. As a result, as shown in FIG. 8A, the insulating layer IL1 (a first insulating layer) is formed. The upper portion of the opening OP1 is plugged by the insulating layer IL1. The insulating layer IL1 is separated from the first layer L1 in the Z-direction; and the gap G is formed between the first layer L1 and the insulating layer IL1. CVD may be performed after ALD when the opening OP1 is wide and it is difficult to plug the opening OP1 by only ALD. By reducing the width of the opening OP1 with ALD, even when CVD is used, the opening OP1 can be plugged with good controllability.

Instead of using the inhibitor i, dangling bonds of the semiconductor material present at the inner surface of the lower portion of the opening OP1 and the side surface of the FP electrode 10 may be terminated. When the dangling bonds are terminated, the precursor p can no longer adhere to the inner surface of the lower portion of the opening OP1. As a result, similarly to when the inhibitor i is used, the insulating layer IL1 is not formed at the inner surface of the lower portion of the opening OP1 and the side surface of the FP electrode 10.

For example, after the process shown in FIG. 6D is performed, the surface of the opening OP1 and the surface of the FP electrode 10 are exposed to nitrogen plasma or hydrogen plasma. As a result, the dangling bonds of the semiconductor material (e.g., silicon) present at these surfaces are terminated. Continuing, etching gas is supplied to the processing chamber in which the semiconductor substrate is placed. At this time, the concentration of the etching gas is set to be low, or the etching gas is supplied for only a short period of time. As a result, the nitrogen gas or hydrogen gas that is adhered to the inner surface of the upper portion of the opening OP1 and the upper surface of the FP electrode 10 is desorbed. The silicon dangling bonds are maintained in the terminated state at the inner surface of the lower portion of the opening OP1 and the side surface of the FP electrode 10. Subsequently, by supplying the precursor p similarly to the process shown in FIG. 7C, the precursor p can be selectively adhered to the inner surface of the upper portion of the opening OP1 and the upper surface of the FP electrode 10.

By performing wet etching, the portion of the insulating layer IL1 formed along the inner surface of the upper portion of the opening OP1 is removed, and the inner surface of the upper portion of the opening OP1 is exposed. As shown in FIG. 8B, an insulating layer IL2 (a second insulating layer) along the exposed inner surface is formed by thermal oxidation. A conductive layer is formed on the insulating layer IL2; and the upper surface of the conductive layer is caused to recede. As a result, as shown in FIG. 8C, the gate electrode 20 is formed on the insulating layer IL1 inside the opening OP1. As shown in FIG. 8D, the insulating layer IL2 that is located around the second conductive part 10b is removed.

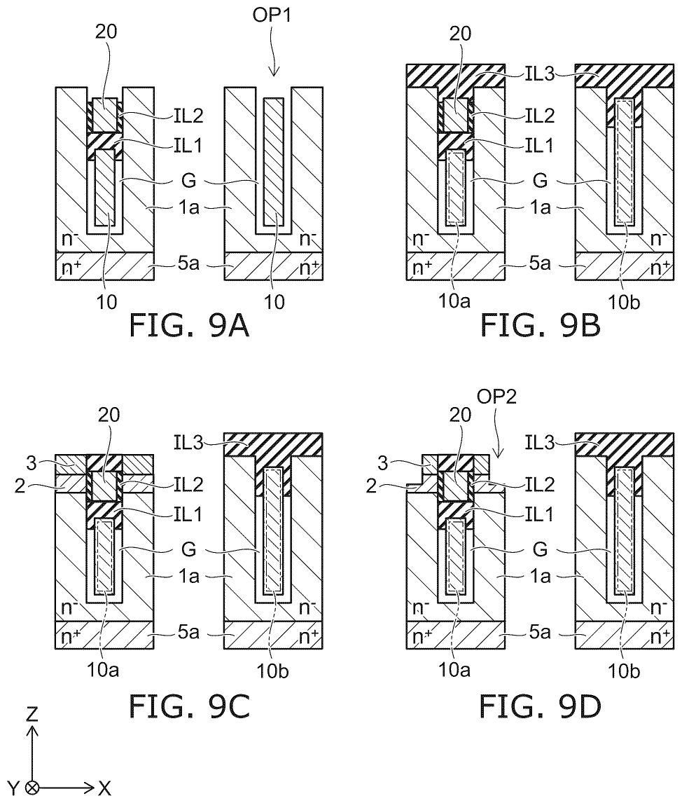

Subsequently, wet etching is performed. At this time, the chemical liquid flows into the opening OP1 at the portion at which the second conductive part 10b is located. The chemical liquid is selected so that the first layer L1 is removed selectively with respect to the insulating layers IL1 and IL2. By this process, the first layer L1 that is positioned at the bottom portion of the opening OP1 between the n-type semiconductor layer 1a and the FP electrode 10 is removed. As shown in FIG. 9A, the gap G spreads between the FP electrode 10 and the n-type semiconductor layer 1a. As an example, when the first layer L1 includes silicon nitride, and the insulating layers IL1 and IL2 include silicon oxide, the first layer L1 can be removed selectively with respect to the insulating layers IL1 and IL2 by wet etching with phosphoric acid.

As shown in FIG. 9B, an insulating layer IL3 is formed on the second conductive part 10b and the gate electrode 20. The opening OP1 is plugged by the insulating layer IL3 at the portion at which the second conductive part 10b is located. A portion of the insulating layer IL3 is removed, and the upper surface of the n-type semiconductor layer 1a adjacent to the gate electrode 20 is exposed. A p-type impurity and an n-type impurity are sequentially ion-implanted into the exposed upper surface of the n-type semiconductor layer 1a. As shown in FIG. 9C, the p-type base region 2 and the n⁺-type source region 3 are formed thereby.

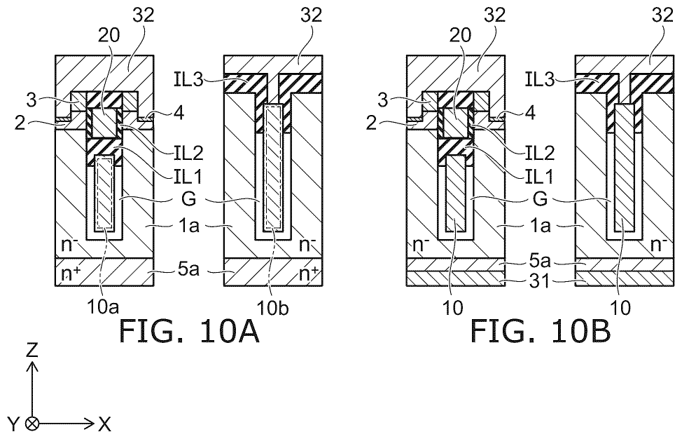

As shown in FIG. 9D, an opening OP2 that extends through the n⁺-type source region 3 and reaches the p-type base region 2 is formed. The p⁺-type contact region 4 is formed by ion-implanting a p-type impurity into a portion of the p-type base region 2 via the opening OP2. The upper surface of the second conductive part 10b is exposed by forming an opening in the insulating layer IL3. A metal layer that covers the n⁺-type source region 3, the p⁺-type contact region 4, and the insulating layer IL3 is formed, and the metal layer is patterned. As shown in FIG. 10A, the source electrode 32 is formed thereby. The gate pad 33 (not illustrated) also is formed.

The back surface of the n⁺-type semiconductor layer 5a is polished until the n⁺-type semiconductor layer 5a has a prescribed thickness. As shown in FIG. 10B, the drain electrode 31 is formed by forming a metal layer at the back surface of the n⁺-type semiconductor layer 5a. The semiconductor device 100 shown in FIGS. 1 to 5 is manufactured by the processes described above.

An insulating part that electrically isolates the n-type semiconductor layer 1a and the FP electrode 10 is located around the FP electrode 10. In the semiconductor device 100, the gap G is provided as the insulating part. The relative dielectric constant of the gap G is less than relative dielectric constants of insulating materials such as silicon oxide, silicon nitride, etc. By using the gap G as the insulating part, the insulating part can be thinner than when an insulating layer made of an insulating material is used. The breakdown voltage of the semiconductor device 100 can be increased thereby.

The reason that the insulating part can be made thin by using the gap G is as follows. It is taken that when the semiconductor device 100 is in the on-state, R_{ch}×A is the channel resistance, L is the channel length, P is the pitch of the gate electrodes 20, μ is the channel mobility, C is the gate capacitance, and V is the overdrive voltage. The overdrive voltage V corresponds to the value of the threshold voltage subtracted from the voltage applied to the gate electrode 20. The relationship of these values is represented by the following Formula 1.

$${R}_{ch} \times A = ( L \times P ) / ( 2 μ \times C \times V ) \qquad Formula 1$$

A charge amount Q generated in the channel is represented by the following Formula 2. The gate capacitance C is represented by the following Formula 3. In Formula 3, cox is the relative dielectric constant of the insulating part located around the FP electrode 10. Tₒₓ is the thickness of the insulating part.

$$Q = C \times V \qquad Formula 2$$

$$C = {ε}_{ox} / {T}_{ox} \qquad Formula 3$$

It can be seen from Formula 3 that, when the channel resistance R_{ch}, the cell pitch P, the gate capacitance C, and the like are constant, the thickness Tₒₓ of the insulating part decreases as the relative dielectric constant εₒₓ decreases.

Advantages of the embodiment will now be described.

Conventionally, the gap G is formed by depositing an insulating layer by CVD to plug the opening OP1. For example, the gap G can be formed by increasing the CVD film formation rate to suppress deposition of the material at the lower portion of the opening OP1. However, methods that use CVD cause large shape and dimensional fluctuation of the deposited insulating layer. As a result, the dimensional and shape fluctuation of the gap G also is increased, and the characteristics of the semiconductor device 100 fluctuate.

For this problem, according to the manufacturing method according to the embodiment, the insulating layer IL1 is formed using ALD as shown in FIGS. 7A to 7D. By adhering the inhibitor i or by performing termination, the adhesion of the precursor p to the lower portion of the opening OP1 in ALD can be suppressed. As a result, an insulating layer can be formed selectively at only the inner surface of the upper portion of the opening OP1 to which the precursor p is adhered. Therefore, compared to when CVD is used, the dimensional and shape fluctuation of the gap G can be reduced. As a result, the semiconductor device 100 can be manufactured with low characteristic fluctuation.

According to the embodiment, a method for manufacturing a semiconductor device is provided in which the dimensional and shape fluctuation of a gap can be suppressed. By using the manufacturing method, the semiconductor device that is obtained has low dimensional and shape fluctuation of the gap.

According to the manufacturing method according to the embodiment, the first layer L1 is provided to support the FP electrode 10 until the insulating layer IL1 is formed. When the first layer L1 is insulative, the first layer L1 may remain without being removed. More favorably, the first layer L1 is removed after forming the insulating layer IL1 as shown in FIG. 9A. After the first layer L1 is removed, a gap is formed in the region at which the first layer L1 was located. Therefore, the breakdown voltage of the semiconductor device 100 can be further improved.

### Modification

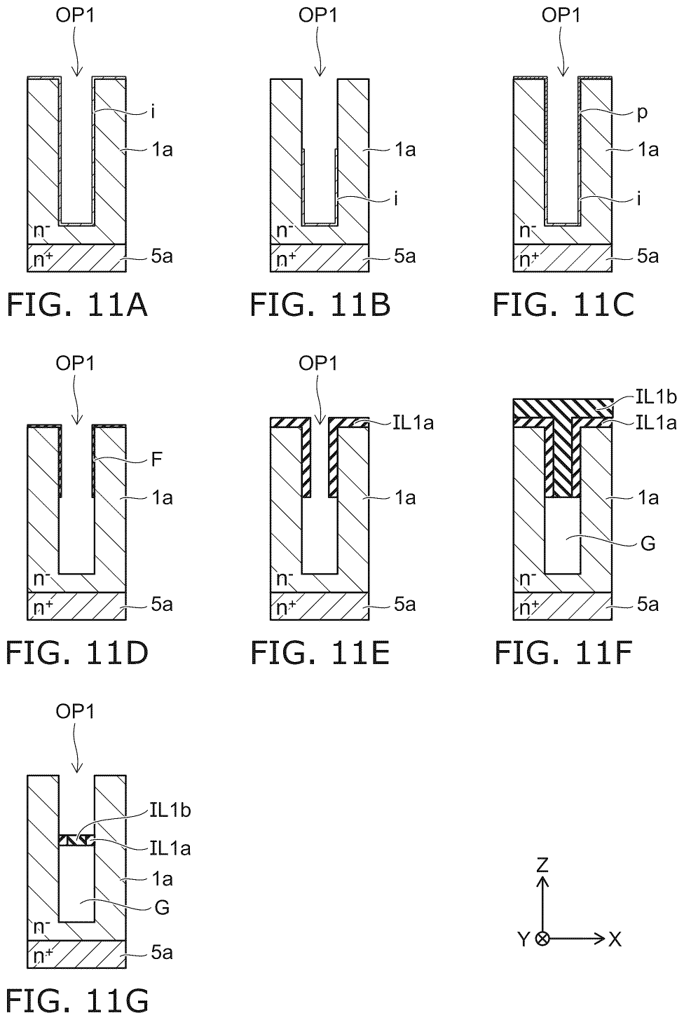

FIGS. 11A to 11G are process cross-sectional views showing a manufacturing method according to a modification of the embodiment.

FIGS. 6A to 10B illustrate a method for manufacturing when the semiconductor device 100 includes the FP electrode 10. The semiconductor device 100 may not include the FP electrode 10. In such a case, it is unnecessary to form the first layer L1 and the FP electrode 10.

First, similarly to the process shown in FIG. 6A, the opening OP1 is formed in the n-type semiconductor layer 1a. Then, as shown in FIG. 11A, the inhibitor i is adhered to the inner surface of the opening OP1. As shown in FIG. 11B, the inhibitor i that is adhered to the inner surface of the upper portion of the opening OP1 is removed. As shown in FIG. 11C, the precursor p is adhered to the inner surface of the upper portion of the opening OP1. Subsequently, the insulating thin film F is formed by supplying a gas and causing the gas to react with the precursor p. The inhibitor i is removed as shown in FIG. 11D.

The processes shown in FIGS. 11A to 11D are repeated. As a result, as shown in FIG. 11E, an insulating layer IL1a is formed at the upper portion of the opening OP1. As shown in FIG. 11F, an insulating layer IL1b is formed on the insulating layer IL1a by CVD. The gap G is formed by the insulating layers IL1a and IL1b plugging the upper portion of the opening OP1. When the opening OP1 is narrow, the upper portion of the opening OP1 may be plugged by the insulating layer IL1a. In such a case, the process shown in FIG. 11F is omissible. Then, portions of the insulating layers IL1a and IL1b are removed, and the inner surface of the upper portion of the opening OP1 is exposed as shown in FIG. 11G. Subsequently, a process similar to the process shown in FIG. 8B is performed.

According to the manufacturing method shown in FIGS. 11A to 11G, the dimensional and shape fluctuation of the gap G formed below the gate electrode 20 can be suppressed. Also, stress that is generated when processing the semiconductor substrate can be relaxed by forming the gap G. Warp of the semiconductor substrate is reduced by relaxing the stress. Or, cracks in the n⁻-type semiconductor layer 1a due to stress can be suppressed. The yield of the manufactured semiconductor device can be increased thereby.

In the embodiments above, the relative levels of the impurity concentrations between the semiconductor regions can be confirmed using, for example, a scanning capacitance microscope (SCM). The carrier concentration in each semiconductor region can be considered to be equal to the activated impurity concentration in each semiconductor region. Accordingly, the relative levels of the carrier concentrations between the semiconductor regions also can be confirmed using SCM. The impurity concentration in each semiconductor region can be measured by, for example, secondary ion mass spectrometry (SIMS).

While certain embodiments of the inventions have been illustrated, these embodiments have been presented by way of example only, and are not intended to limit the scope of the inventions. These novel embodiments may be embodied in a variety of other forms; and various omissions, substitutions, modifications, etc., can be made without departing from the spirit of the inventions. These embodiments and their modifications are within the scope and spirit of the inventions and are within the scope of the inventions described in the claims and their equivalents. The embodiments described above can be implemented in combination with each other.

What is claimed is:

1. A method for manufacturing a semiconductor device, the method comprising:
forming an opening in an upper surface of a first semiconductor region of a first conductivity type; and
forming a gap at a lower portion of the opening by performing atomic layer deposition to form a first insulating layer at an upper portion of the opening so as to plug the opening,
the atomic layer deposition including repeatedly performing
adsorption of an inhibitor to an inner surface of the lower portion of the opening, or termination of dangling bonds of a semiconductor material present at the inner surface of the lower portion of the opening, and
adsorption of a precursor to an inner surface of the upper portion of the opening.

2. The method according to claim 1, further comprising:
forming a gate electrode on the first insulating layer inside the opening after the forming of the gap.

3. The method according to claim 2, further comprising:
forming a first layer and a conductive part after the forming of the opening,
the first layer being positioned at a bottom portion of the opening,
the conductive part being positioned on the first layer,
the first insulating layer being formed along the inner surface of the upper portion of the opening and along an upper surface of the conductive part.

4. The method according to claim 3, further comprising:
after the forming of the gap, removing a portion of the first insulating layer formed along the inner surface of the upper portion;
forming a second insulating layer along the inner surface of the upper portion by thermal oxidation; and
forming the gate electrode after the forming of the second insulating layer.

5. The method according to claim 4, further comprising:
removing the first layer after the forming of the gate electrode.
